(19) United States
(12) Patent Application Publication
(10) Pub. No.: US 2023/0154744 A1
(43) Pub. Date: May 18, 2023

(54) METHOD AND APPARATUS FOR FORMING SILICON CARBIDE-CONTAINING FILM

(71) Applicant: Tokyo Electron Limited, Minato-ku, Tokyo (JP)

(72) Inventors: Susumu YAMAUCHI, Nirasaki City, Yamanashi (JP); Makoto FUJIKAWA, Nirasaki City, Yamanashi (JP)

(21) Appl. No.: 17/906,775

(22) PCT Filed: Mar. 12, 2021
(86) PCT No.: PCT/JP2021/010183

§ 371 Date: Sep. 20, 2022

(30) Foreign Application Priority Data
Mar. 25, 2020 (JP) 2020-054008

(51) Int. Cl. H01L 21/02; C23C 16/32; C23C 16/455; C23C 16/44

(52) U.S. Cl. CPC H01L 21/02167; C23C 16/325; H01L 21/02211; C23C 16/45527; C23C 16/45544; C23C 16/4412; C23C 16/45557; H01L 21/0228

(57) ABSTRACT

A method of forming a silicon carbide-containing film on a substrate in a processing container. The method includes: accommodating the substrate in the processing container; adsorbing an organic compound on the substrate by supplying a carbon precursor gas to the processing container; and reacting the organic compound adsorbed on the substrate with a silicon compound by supplying a silicon precursor gas including the silicon compound to the processing container. The adsorbing the organic compound on the substrate and the reacting the organic compound are alternately repeated multiple times. In the adsorbing the organic compound, the vacuum exhaust is restricted, and then the restriction of the vacuum exhaust is released. The supply of the silicon precursor gas is stopped during the reacting the organic compound with the silicon compound, and the vacuum exhaust is not restricted after the supply of the silicon precursor gas is stopped.

### TECHNICAL FIELD

The present disclosure relates to a method and apparatus for forming a silicon carbide-containing film.

### BACKGROUND

In multi-gate type fin-field effect transistors (Fin-FETs) or the like, which are semiconductor elements, the degree of integration is further increased, and film types may be exposed in openings formed in hard masks. Therefore, there is an increasing need for a hard mask material capable of etching a desired film with a high selectivity between films exposed in a fine opening. As a material satisfying this demand, inventors have developed a film forming technology for a silicon carbide-containing film (hereinafter, referred to as a “SiC film”).

Regarding a SiC film, Patent Document 1 describes a method of obtaining a SiC film at a high temperature of 900 degrees C. to 1,100 degrees C. by alternately supplying acetylene gas and dichlorosilane gas into a reaction tube. In addition, Patent Document 2 describes a method of forming a SiC film by simultaneously supplying triethylamine gas and disilane gas into a processing chamber. In this method, a pressure regulating valve is closed after the simultaneous supply of both gases, and the triethylamine gas and the disilane gas are enclosed in the processing chamber to improve gas phase reaction efficiency.

### PRIOR ART DOCUMENTS

### Patent Documents

Patent Document 1: Japanese laid-open publication No. H05-1380
Patent Document 2: Japanese laid-open publication No. 2013-30752

The present disclosure provides a technique capable of forming a silicon carbide-containing film having a good film quality and improving a film forming rate.

### SUMMARY

According to one embodiment of the present disclosure, there is provided a method of forming a silicon carbide-containing film on a substrate in a processing container in which vacuum exhaust is performed. The method includes: accommodating the substrate in the processing container; adsorbing an organic compound having an unsaturated carbon bond on the substrate by supplying a carbon precursor gas including the organic compound to the processing container in which the substrate is accommodated; and reacting the organic compound adsorbed on the substrate with a silicon compound by supplying a silicon precursor gas including the silicon compound to the processing container after the carbon precursor gas is supplied. The adsorbing the organic compound on the substrate and the reacting the organic compound with the silicon compound are alternately repeated multiple times to form the silicon carbide-containing film. In the adsorbing the organic compound, the vacuum exhaust is restricted to cause the carbon precursor gas to stay in the processing container, and then the restriction of the vacuum exhaust is released to discharge the carbon precursor gas in the processing container. The supply of the silicon precursor gas to the processing container is stopped during the reacting the organic compound adsorbed on the substrate with the silicon compound, and the vacuum exhaust is not restricted after the supply of the silicon precursor gas is stopped.

According to the present disclosure, it is possible to form a silicon carbide-containing film having a good film quality and to improve a film forming rate.

### BRIEF DESCRIPTION OF DRAWINGS

FIG. 1 is a vertical cross-sectional side view illustrating an example of a film forming apparatus of the present disclosure.

FIG. 2 illustrates an example of a chemical reaction formula used in a film forming method of the present disclosure.

FIG. 3 illustrates an example of a reaction model related to the chemical reaction formula.

FIG. 4A is a time chart illustrating an example of a film forming method.

FIG. 4B is a time chart illustrating another example of the film forming method.

FIGS. 5A and 5B illustrate a structural formula illustrating another example of a carbon precursor.

FIG. 6 illustrates an example of another chemical reaction formula used in the film forming method.

FIG. 7 illustrates an example of a reaction model related to the other chemical reaction formula.

FIG. 8 is an explanatory view illustrating a variation of a carbon precursor.

FIG. 9 is an explanatory view illustrating a variation of a silicon precursor.

FIG. 10 is a time chart illustrating another example of a film forming method.

FIG. 11 is a vertical cross-sectional side view illustrating another example of a film forming apparatus.

FIG. 12 is a characteristic diagram showing an evaluation result of a film forming method.

FIG. 13 is a characteristic diagram showing an evaluation result of a film forming method.

### DETAILED DESCRIPTION

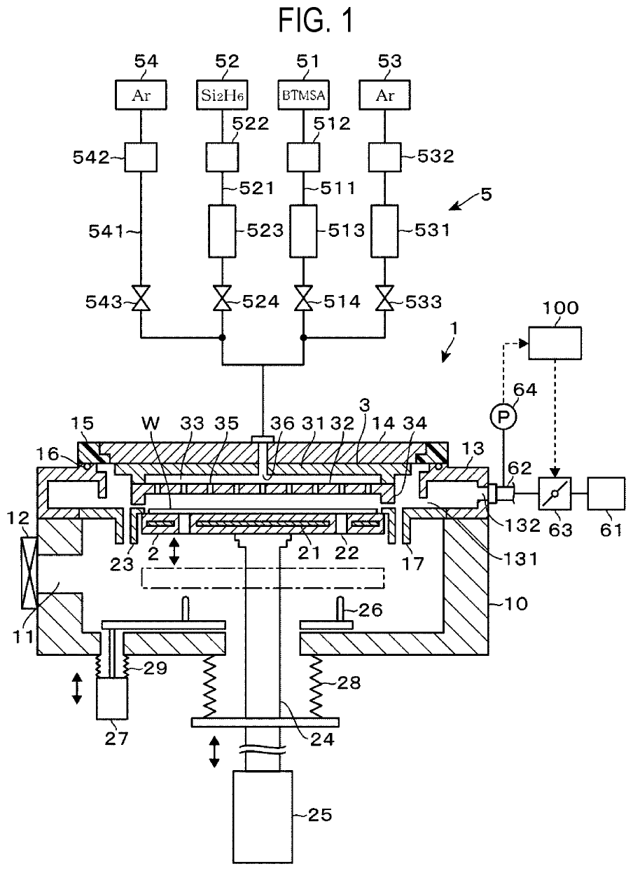

A single-wafer-type film forming apparatus according to an embodiment of an apparatus (hereinafter, referred to as a “film forming apparatus”) for executing a method of forming a silicon carbide-containing film (hereinafter referred to as a “film forming method”) of the present disclosure will be described with reference to FIG. 1. The film forming apparatus 1 includes a processing container 10 that accommodates a substrate, for example, a semiconductor wafer (hereinafter, referred to as a “wafer”) W, and the processing container 10 is formed of a metal such as aluminum (Al) in a substantially cylindrical shape. A carry-in/out port 11 for carrying in or out a wafer W is formed in the side wall of the processing container 10 to be openable/closable by a gate valve 12.

An annular exhaust duct 13 having, for example, a rectangular cross section is disposed in an upper portion of the side wall of the processing container 10. The exhaust duct 13 has a slit 131 along the inner peripheral surface thereof, and an exhaust port 132 is formed in the outer wall of the exhaust duct 13. A ceiling wall 14 is installed on the top surface of the exhaust duct 13 to close an upper opening of the processing container 10 via an insulating member 15, and the space between the exhaust duct 13 and the insulating member 15 is hermetically sealed with a seal ring 16.

A stage 2 for horizontally supporting a wafer W is provided inside the processing container 10, and the stage 2 is made of a ceramic material such as aluminum nitride (AlN) or a metal material such as aluminum or nickel alloy in a disk shape. In this example, a heater 21 forming a heating part for heating the wafer W is embedded in the stage 2, and the outer peripheral region and the side surface of the top surface of the stage 2 are covered with a cover member 23 made of ceramic such as alumina.

The stage 2 is connected to a lifting mechanism 25 installed below the processing container 10 via a support member 24, and is configured to be moved up and down between a processing position indicated by the solid line in FIG. 1 and a wafer W delivery position indicated by the alternate long and short dash line below the processing position. In FIG. 1, reference numeral 17 indicates a partition member for partitioning the interior of the processing container 10 into upper and lower portions when the stage 2 is raised to the processing position. Three support pins 26 (only two of which are illustrated) are provided below the stage 2 in the processing container 10 to be movable up and down by a lifting mechanism 27 provided below the processing container 10. The support pins 26 are inserted through through-holes 22 in the stage 2 located at the delivery position to be capable of protruding/sinking with respect to the top surface of the stage 2, and are used for delivery of a wafer W between an external transport mechanism (not illustrated) and the stage 2. Reference numerals 28 and 29 in the figure denote bellows that partition the atmosphere inside the processing container 10 from the outside air and expand/contract according to the moving-up/down operations of the stage 2 and the support pins 26, respectively.

A shower head 3 for supplying a processing gas in a shower form in the processing container 10 is installed in the processing container 10 to face the stage 2. The shower head 3 includes a main body 31 fixed to the ceiling wall 14 of the processing container 10 and a shower plate 32 connected under the main body 31, and the interior thereof forms a gas diffusion space 33. An annular protrusion 34 protruding downward is formed at the peripheral edge of the shower plate 32, and gas ejection holes 35 are formed in the flat surface inside the annular protrusion 34. A gas supply system 5 is connected to the gas diffusion space 33 via a gas introduction hole 36.

The gas supply system 5 includes a carbon precursor supplier configured to supply a carbon precursor gas to the processing container 10 and a silicon precursor supplier configured to supply a silicon precursor gas. The carbon precursor supplier includes a carbon precursor gas source 51 and a gas supply path 511, and the gas supply path 511 is provided with a flow rate regulator 512, a storage tank 513, and a valve 514 from the upstream side.

The carbon precursor contains an organic compound having an unsaturated carbon bond. For example, bis(trimethylsilyl)acetylene (BTMSA) having a triple bond is used. Hereinafter, the carbon precursor gas may be referred to as carbon precursor gas or BTMSA gas. The carbon precursor gas supplied from the source 51 is temporarily stored in the storage tank 513, pressurized to a predetermined pressure in the storage tank 513, and then supplied into the processing container 10. BTMSA is a liquid at room temperature, and the gas obtained by heating the BTMSA is supplied to and stored in the storage tank 513. The supplying and stopping of the carbon precursor gas from the storage tank 513 to the processing container 10 is performed by opening and closing the valve 514.

The silicon precursor supplier includes a silicon precursor gas source 52 and a gas supply path 521, and the gas supply path 521 is provided with a flow rate regulator 522, a storage tank 523, and a valve 524 from the upstream side. The silicon precursor contains a silicon compound, and, for example, disilane (Si₂H₆) is used. Here, the gas of the silicon precursor may be referred to as silicon precursor gas or disilane gas. The silicon precursor gas supplied from the source 52 is temporarily stored in the storage tank 523, pressurized to a predetermined pressure in the storage tank 523, and then supplied into the processing container 10. The supplying and stopping of the silicon precursor gas from the storage tank 523 to the processing container 10 is performed by opening and closing the valve 524.

In addition, the gas supply system 5 includes sources 53 and 54 of an inert gas such as argon (Ar) gas. In this example, the Ar gas supplied from one source 53 is used as a purge gas for carbon precursor gas. The source 53 is connected from the upstream side to the downstream side of the valve 514 in the gas supply path 511 of the carbon precursor gas via a gas supply path 531 provided with a flow rate regulator 532 and a valve 533.

The Ar gas supplied from the other source 54 is used as a purge gas for silicon precursor gas. The source 54 is connected from the upstream side to the downstream side of the valve 524 in the gas supply path 521 of the silicon precursor gas via a gas supply path 541 provided with a flow rate regulator 542 and a valve 543. The supplying and stopping of the Ar gas to the processing container 10 is performed by opening and closing the valves 533 and 543.

The processing container 10 is connected to a vacuum exhaust path 62 via an exhaust port 132, and a vacuum exhauster 61 configured to execute vacuum exhaust of the gas in the processing container 10 and including, for example, a vacuum pump, is installed on the downstream side of the vacuum exhaust path 62. In the vacuum exhaust path 62, for example, an auto pressure controller (APC) valve 63 is interposed between the processing container 10 and the vacuum exhauster 61, as a pressure control valve.

The interior of the processing container 10 is configured such that the pressure is regulated by a pressure regulating mechanism. The pressure regulating mechanism of this example includes a vacuum exhauster 61, a vacuum exhaust path 62, and an APC valve (pressure regulating valve) 63. The APC valve 63 is constituted with, for example, a butterfly valve, and provided to be capable of opening/closing the vacuum exhaust path 62, and has a role of regulating the pressure in the processing container 10 by increasing or decreasing the conductance of the vacuum exhaust path 62 by regulating the opening degree of the same.

As described above, the APC valve 63 is opened and closed to regulate the pressure in the processing container 10, and the exhaust in the processing container 10 is hindered and the exhaust flow rate is decreased by reducing the opening degree of the APC valve 63. In the vacuum exhaust path 62, for example, a pressure detector 64 is installed between the exhaust port 132 and the APC valve 63. The pressure detector 64 is installed in the immediate vicinity of the exhaust port 132, and the pressure detection value thereof may be regarded as the pressure detection value in the processing container 10.

The APC valve 63 in this example has a pressure regulating function and an opening degree setting function. The pressure regulating function is a function of controlling the pressure by regulating the opening degree based on the pressure detection value by the pressure detector 64 and a preset pressure target value. The opening degree setting function is a function of fixing the opening degree of the valve body to a preset opening degree. Then, in the film forming process of a SiC film to be described later, the pressure regulating function and the opening degree setting function are switched based on a command from a controller 100.

The controller 100 is constituted with, for example, a computer, and includes a data processor including a program, a memory, and a CPU. In the program, commands (respective steps) are incorporated such that the controller 100 sends control signals to each part of the film forming apparatus 1 so as to proceed with a film forming process of a SiC film to be described later. The program is stored in a storage, such as a computer storage medium such as a flexible disk, a compact disk, a hard disk, a magneto-optical disk (MO), or the like, and is installed in the controller 100.

Specifically, the controller 100 is configured to control the film forming process for forming a SiC film on a wafer W. In the film forming process of this example, an adsorption step of adsorbing BTMSA on a wafer W by supplying BTMSA gas as a carbon precursor is performed. Next, a reaction step of reacting BTMSA adsorbed on the wafer W with disilane is executed by supplying disilane gas as a silicon precursor. Then, control of forming a SiC film by an atomic layer deposition (ALD) method is executed by alternately repeating the adsorption step and the reaction step multiple times.

In the adsorption step, the controller 100 is configured to temporarily restrict the vacuum exhaust in the processing container 10 by controlling the vacuum exhaust performed by the vacuum exhauster 61. In this vacuum exhaust control, after making the carbon precursor gas stay in the processing container 10, the restriction on the vacuum exhaust is released, and the control is executed such that the carbon precursor gas in the processing container 10 is discharged.

Further, the controller 100 is configured to perform control of initiating the restriction of vacuum exhaust during the period of supplying the carbon precursor gas to the processing container 10 and terminating the restriction after a lapse of a preset time after the stop of the supply of the gas. The controller 100 is also configured to perform control of stopping the supply of the silicon precursor gas to the processing container 10 during the reaction step and continuing the vacuum exhaust by the vacuum exhauster 61 such that the restriction of the vacuum exhaust is not performed after the stopping of the supply.

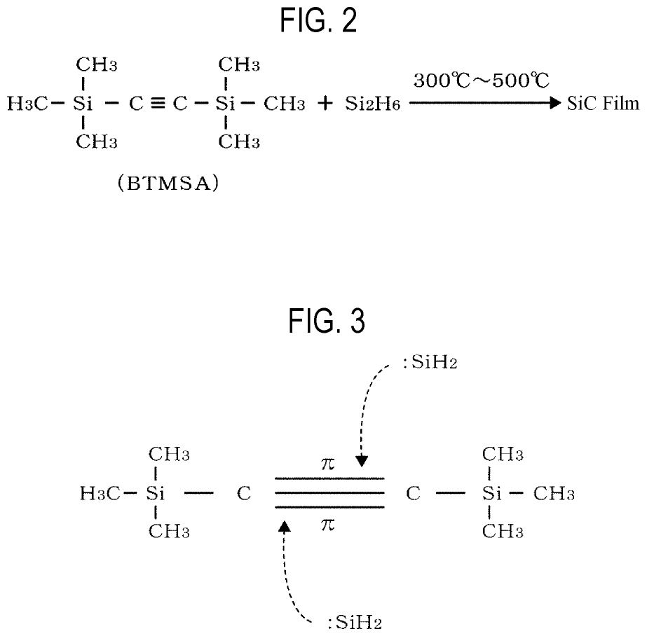

Subsequently, the film forming method executed by the film forming apparatus 1 will be described. As described above, the film forming method of the present disclosure forms a SiC film by an ALD method using a carbon precursor gas and a silicon precursor gas and by a thermal reaction of 500 degrees C. or low without using plasma. FIG. 2 illustrates an example in which BTMSA, which is a carbon precursor and has a triple bond, and disilane, which is a silicon precursor, are thermally reacted at a temperature in the range of, for example, 300 degrees C. or higher and 500 degrees C. or lower.

The mechanism that is capable of forming a SiC film by such a thermal reaction at a low temperature will be considered by using Reaction Model 1 illustrated in FIG. 3. Disilane is thermally decomposed by heating at a temperature near 400 degrees C. to generate a SiH₂ radical having an unpaired electron in the Si atom, wherein the SiH₂ radical has an empty p-orbital. In Reaction Model 1, this empty p-orbital acts as an electrophile that attacks a π bond of an unsaturated carbon bond of electron-rich BTMSA and acts on the triple bond of BTMSA. Then, Reaction Model 1 is a model in which C forming the triple bond reacts with Si of the SiH₂ radical to form a SiC bond.

Since the π bond of the BTMSA triple bond has a smaller bond force than a σ bond, it is presumed that if a SiH₂ radical attacks this π bond, a thermal reaction proceeds even at a temperature of 500 degrees C. or lower, forming a SiC bond. Reaction Model 1 is for presuming the reason why the formation of SiC film at a low temperature, which has been considered difficult in the past, is enabled and does not limit an actual reaction route. If it is possible to form the SiC film at a temperature of 500 degrees C. or lower without using plasma, the SiC film may be formed via another reaction path.

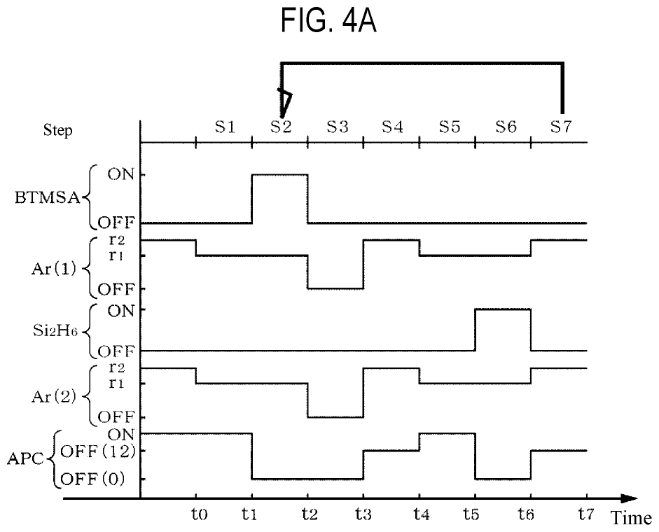

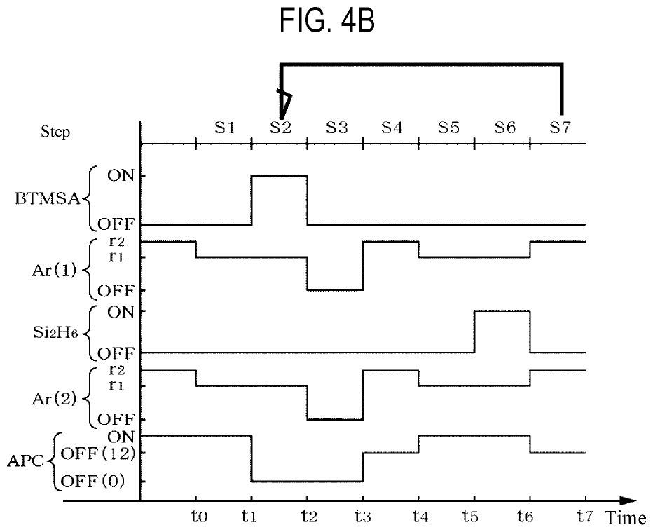

Next, an example of the film forming method of the present disclosure will be described with reference to the time charts of FIGS. 4A and 4B. FIGS. 4A and 4B each illustrate the timing of initiating and stopping the supply of each of BTMSA gas, Ar gas, and disilane gas, and the timing of opening and closing the APC valve 63. For BTMSA gas and disilane gas, “ON” and “OFF” on the vertical axis indicate the supply state and the supply stop state, respectively. In addition, Ar(1) indicated in FIGS. 4A and 4B refers to Ar gas for purging BTMSA gas, and Ar(2) in FIG. 4B refers to Ar gas for purging disilane gas.

In addition, “ON” of the APC valve 63 means that the pressure regulating function of the APC valve 63 is set to “ON” and the opening degree is regulated to approach the pressure target value based on the pressure detection value. Meanwhile, “OFF” of the APC valve 63 means that the pressure regulating function is set to “OFF” and the opening degree of the APC valve 63 is regulated to the set opening degree by the opening degree setting function. “OFF(0)” means that the opening degree is set to 0%, that is, the fully closed state, and “OFF(12)” means that the opening degree is set to 12%.

The film forming process will be described with reference to FIG. 4A. First, the step of accommodating a wafer W in the processing container 10 by carrying the wafer W into the processing container 10 and closing the gate valve 12 of the processing container 10 is performed. Then, the heating of the wafer W by the heater 21 is initiated, and the vacuum exhauster 61 executes vacuum exhaust in the processing container 10. In addition, the APC valve 63 controls the interior of the processing container 10 to a pressure target value of, for example, 1,000 Pa by setting the pressure regulating function to “ON” and performing opening/closing control based on the pressure detection value detected by the pressure detector 64.

At time t0, a first pressure regulating step S1 is executed by supplying each of Ar(1) and Ar(2), which are purge gases, into the processing container 10 at a first flow rate r1, for example, 50 sccm. Ar(1) and Ar(2) are introduced into the processing container 10 via the shower head 3, flow toward the exhaust port 132 on the side of the wafer W placed on the stage 2 located at the processing position, and are discharged from the processing container 10 via the vacuum exhaust path 62.

Next, at time t1, the valve 514 is opened to initiate the supply of the BTMSA gas, which is a carbon precursor, to the processing container 10, and the adsorption step of adsorbing BTMSA on the wafer W is initiated. First, a BTMSA supply step S2 is executed by opening the valve 512 to supply the BTMSA gas stored in the storage tank 513 into the processing container 10 in a short time. At this time, for example, Ar(1) and Ar(2) continue to be supplied at the first flow rate r1.

Next, at time t2, a BTMSA enclosing step S3 is performed by closing the valve 514 to stop the supply of BTMSA. At this time, for example, the supply of Ar(1) and Ar(2) is stopped. In this example, the adsorption step includes the BTMSA supply step S2 and the BTMSA enclosing step S3. In this adsorption step, the heater 21 heats the wafer W to a temperature in the range of 300 degrees C. or higher and 500 degrees C. or lower, for example, 410 degrees C.

In this adsorption step, the BTMSA enclosing step S3 is provided after the BTMSA supply step S2, and during the periods of these steps, the BTMSA gas is caused to stay in the processing container 10 by temporarily limiting the vacuum exhaust in the processing container 10. In this example, at time t1, the control of the APC valve 63 is switched to the opening degree setting function, and the opening degree is set to “0%”, that is, to the fully closed state. As a result, during the periods of the BTMSA supply step S2 and the BTMSA enclosing step S3, the exhaust of the gas in the processing container 10 is temporarily substantially stopped. Therefore, by performing the above operation, it is possible to maintain the state in which the BTMSA gas sufficiently stays in the processing space formed between the shower head 3 and the stage 2.

In general, the APC valve 63 does not have a function of separating the upstream side and the downstream side thereof, and even if the APC valve 63 is set to the fully closed state, gas may continue to be discharged from the processing container 10 although the amount is small. Even in such a case, it has been found that the effect of causing the BTMSA gas to stay in the processing container 10 is obtained compared with the case where the APC valve 63 is in the opened state.

By the above-mentioned restriction of vacuum exhaust, compared with the case where vacuum exhaust is continued, the time in which the BTMSA gas stays in the processing container 10 is extended so that the time for bringing the BTMSA gas into contact with the wafer W can be lengthened. As a result, even when the chemisorption between the surface of the wafer W and the BTMSA proceeds relatively slowly, it is possible to sufficiently secure the time required for the chemisorption, so that a sufficient amount of BTMSA can be adsorbed on the surface of the wafer W.

As described above, the temporary restriction of the vacuum exhaust in the processing container 10 is executed by making the opening degree of the APC valve 63 smaller than that before the restriction is initiated. Therefore, not only the case where the APC valve 63 is fully closed as in the above-mentioned example, but also the case where the opening degree of the APC valve 63 is made smaller than that before the restriction is initiated is included. When the opening degree of the APC valve 63 is made smaller than that before the initiation of the restriction, the exhaust of the carbon precursor gas in the processing container 10 is suppressed and the exhaust flow rate is lowered, so that the gas stays in the processing container 10. Therefore, depending on the type of the carbon precursor gas and the film quality of the target SiC film, the organic compound in the gas may be sufficiently adsorbed on the wafer W even if the APC valve 63 is not fully closed.

Then, at time t3 after the set time elapses from time t1 when the APC valve 63 is fully closed, the restriction on vacuum exhaust is released and the BTMSA gas staying in the processing container 10 is discharged. Specifically, at time t3, a first purge step S4 is performed by setting the opening degree of the APC valve 63 to, for example, 12%, and supplying each of Ar(1) and Ar(2) at a second flow rate r2, for example, 500 sccm. In step S4, by fixing the opening degree of the APC valve 63 at 12%, the forced exhaust in the processing container 10 proceeds.

As a result, the excess BTMSA gas and Ar gas in the processing container 10 are quickly discharged from the processing container 10, and the atmosphere in the processing container 10 is replaced with Ar gas. Next, at time t4, the pressure regulating function of the APC valve 63 is switched to “ON”, Ar(1) and Ar(2) are supplied at the first flow rate r1, and the second pressure regulating step S5 is performed. In step S5, the opening degree of the APC valve 63 is regulated based on the pressure detection value such that the interior of the processing container 10 approaches the pressure target value. The second pressure regulating step in step S5 may be omitted in order for throughput improvement or the like.

In this example, the adsorption step is from time t1 to time t3 when the purging of Ar gas is initiated. Then, the temporary restriction of the vacuum exhaust is initiated at time t1 during the period of supplying the BTMSA gas to the processing container 10 and is terminated at t3 after a lapse of the preset time. Therefore, the period after the supply of the BTMSA gas is stopped at time t2 is also included in the period in which the vacuum exhaust is restricted.

Time t3 is appropriately set depending on the type of carbon precursor gas, the target SiC film quality, and the like. As an example, the supply time of the BTMSA gas is 1 second, and the time for temporarily restricting the vacuum exhaust is 3 seconds or more, preferably 10 seconds or more.

In the adsorption step, the pressure inside the processing container 10 fluctuates by temporarily restricting the vacuum exhaust of the processing container 10, but as described above, the time of supplying the BTMSA gas and the time of temporarily restricting the vacuum exhaust are short. Therefore, the amount of pressure fluctuation in the processing container 10 is not so large, and does not have a large effect of deteriorating the film quality of the formed SiC film.

Next, at time t5, the disilane supply step S6 is executed by opening the valve 524 to initiate the supply of disilane gas, which is the silicon precursor. This step S6 is a reaction step of reacting the BTMSA adsorbed on the wafer W with disilane. The disilane gas is supplied for a relatively short time, for example, 1 second, until the valve 524 is closed and the supply is stopped at time t6. By the operation of opening the valve 524, the disilane gas stored in the storage tank 523 is supplied into the processing container 10 in a short time. At this time, for example, Ar(1) and Ar(2) are supplied at the first flow rate r1.

In the disilane gas supply step S6, the disilane gas is caused to stay in the processing container 10 by temporarily restricting the vacuum exhaust in the processing container 10. In this example, at time t5, the control of the APC valve 63 is switched to the opening degree setting function and the opening degree is set to “0%”, that is, to the fully closed state. That is, the exhaust in the processing container 10 is temporarily and substantially stopped for a relatively short time from time t5 at which the supply of the disilane gas is initiated to time t6 at which the supply is stopped. Therefore, by performing the above operation, in the state of being filled in the processing space formed between the shower head 3 and the stage 2, the disilane gas comes into contact and reacts with the BTMSA adsorbed on the wafer W to form SiC.

Then, at time t6, a second purge step S7 is performed by setting the opening degree of the APC valve 63 to, for example, 12%, and supplying each of Ar(1) and Ar(2) at the second flow rate r2. In this step S7, the forced exhaust in the processing container 10 proceeds by fixing the opening degree of the APC valve 63 to 12%. As a result, the excess disilane gas and Ar gas in the processing container 10 are quickly discharged from the processing container 10. Thereafter, steps 2 to 7 are repeated again.

In this reaction step, as illustrated in FIG. 4B, the vacuum exhaust of the processing container 10 may be controlled to be continued without temporarily restricting the vacuum exhaust. Since the time chart of FIG. 4B is the same as that of FIG. 4A except for the control of the APC valve 63 in the disilane supply step S6, the description other than the APC valve 63 of step S6 will be omitted. In this example, the APC valve 63 switches the pressure regulating function to “ON” at time t4 when the second pressure regulating step S5 is started, and in the disilane supply step S6, the opening degree is also regulated such that the interior of the processing container 10 approaches the pressure target value based on the pressure detection value. The disilane gas introduced from the shower head 3 comes into contact and reacts with the BTMSA adsorbed on the wafer W while flowing through the processing container 10 toward the exhaust port 132, thereby forming SiC.

When the excess disilane gas is decomposed on the surface of the wafer W, amorphous Si may be deposited and an amorphous Si film may be formed. Therefore, as illustrated in FIG. 4A, purging is performed immediately after the supply of the disilane gas is stopped, or as shown in FIG. 4B, the vacuum exhaust in the processing container 10 is continued during the supply period of the disilane gas. In other words, in the case of disilane gas, by not providing the enclosing step in the case of BTMSA and not performing the restriction of vacuum exhaust after the supply the disilane gas is stopped, it is possible to suppress the formation of an amorphous Si film.

In this way, the supply of the BTMSA gas, which is the carbon precursor of step S2, is initiated again, and the step of adsorbing BTMSA on the wafer W and the step of reacting BTMSA with disilane are alternately performed multiple times as in the above-described method to form a SiC film having a predetermined thickness. The SiC film formed in this way by an ALD method is surely formed with a Si—C bond. As described in the Examples to described later, when the chemical bond state was analyzed by X-ray Photoelectron Spectroscopy (XPS), the formation of a bond between Si and C (Si—C bond) was observed.

According to the above-described embodiment, in the step of adsorbing BTMSA on a substrate by supplying a carbon precursor, for example, BTMSA gas, the vacuum exhaust in the processing container 10 is restricted to cause the BTMSA gas to stay in the processing container 10. Therefore, as described above, the chemisorption of BTMSA on the wafer surface is promoted so that a SiC film having good film quality can be formed and the film forming rate can be improved.

The SiC film having a good film quality is a film having a good ratio of a silicon (Si) component and a carbon (C) component (Si/C ratio) in the SiC film, and specifically, a film having a Si/C ratio close to 1. From the examples to described later, it has been recognized that the method of the present disclosure increases the number of carbon atoms (C) having a Si—C bond in the SiC film.

Meanwhile, in the step of reacting the BTMSA adsorbed on the wafer W with disilane by supplying a silicon precursor, for example, disilane gas, the restriction of vacuum exhaust in the processing container 10 is not performed at least after the supply stop of disilane gas (step S7 in FIGS. 4A and 4B). Therefore, the excess disilane gas not used for the reaction with the BTMSA is rapidly discharged from the processing container 10, and the formation of the above-mentioned amorphous Si film is suppressed. Therefore, from this point as well, since the increase of the Si component in the SiC film is suppressed, it is possible to suppress the formation of the amorphous Si film and to form a film having a good Si/C ratio.

In addition, the SiC film formed by thermally reacting the carbon precursor and the silicon precursor at a relatively low temperature of 300 degrees C. or higher and 500 degrees C. or lower by using the ALD method is of high quality, and has properties suitable for a hard mask material, an insulating film, a low dielectric constant film, or the like. When a SiC film is used for a transistor of a semiconductor element, it may be required that the allowable temperature during the film forming process be 500 degrees C. or lower in order to suppress the diffusion of metal from a metal wiring layer. Meanwhile, even if it is possible to form a film at a low temperature of 400 degrees C. or lower, the method of forming a SiC film by using plasma may cause a problem because other films and wiring layers constituting the semiconductor element may be greatly damaged by plasma. Therefore, it is effective to be able to form a SiC film at a temperature of 500 degrees C. or lower without using plasma by the film forming method of the present disclosure, which leads to the expansion of applications of the SiC film.

Here, BTMSA has less intramolecular polarization (localization of electric charge), and is less likely to be chemisorbed on the surface of the wafer W compared with a molecule having more polarization. Therefore, in a method such as an ALD method in which the supply of BTMSA gas is repeated for a short time, when vacuum exhaust is performed in the adsorption step, BTMSA may be discharged from the processing container 10 before being sufficiently chemisorbed. As a result, there are problems that since C components in the SiC film are reduced, it is impossible to form a desired SiC film having a Si/C ratio and the film forming rate is low.

In order to solve the above problems, a method of increasing the supply flow rate and supply time of BTMSA gas in the adsorption step to increase the total amount of BTMSA to be supplied to the surface of the wafer W may also be considered. However, this method leads to a large amount of consumption of BTMSA gas and increases the time required for the adsorption step, so there is a concern that the productivity decreases. In contrast, according to the method of the present disclosure, since it is not necessary to lengthen the supply time of BTMSA gas, it is possible to improve the film forming rate while forming a SiC film having good film quality.

In the above example, since the restriction of vacuum exhaust in the processing container 10 is executed by reducing the opening degree of the APC valve 63, it is easy to control the restriction. Furthermore, when BTMSA is used as the carbon precursor, the BTMSA does not form a thermal decomposition film by itself. Thus, there is an advantage in that a SiC film can be easily formed by an ALD method.

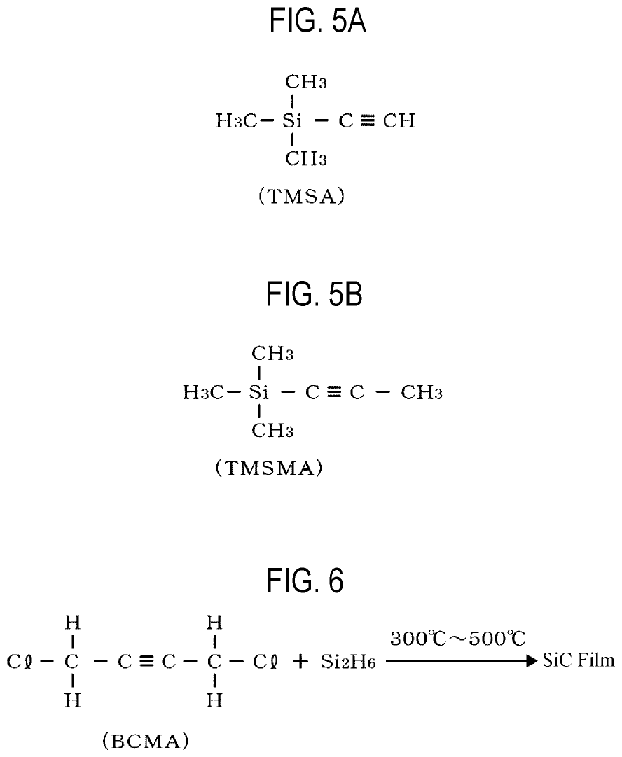

Subsequently, another example of the carbon precursor containing an organic compound having an unsaturated carbon bond will be described with reference to FIGS. 5A to 8. The carbon precursor illustrated in FIG. 5A is trimethylsilylacetylene (TMSA) having a triple bond. The carbon precursor illustrated in FIG. 5B is [(trimethylsilyl)methyl]acetylene (TMSMA) having a triple bond. A SiC film may also be formed by thermally reacting these TMSA gas and TMSMA gas with a silicon precursor, for example, disilane gas, at a temperature in the range of 300 degrees C. or higher and 500 degrees C. or lower.

In these TMSA and TMSMA as well, an empty p-orbital of a SiH₂ radical obtained by thermal decomposition of disilane attacks a π bond of a triple bond. Then, it is presumed that the empty p-orbital acts on the triple bond of TMSA and TMSMA, and the C of the triple bond reacts with the Si of the SiH₂ radical, thereby forming a SiC bond. In addition, TMSA and TMSMA also have less intramolecular polarization and are less likely to cause chemisorption on a wafer surface, but by temporarily restricting vacuum exhaust in the adsorption step, chemisorption with the wafer can be promoted.

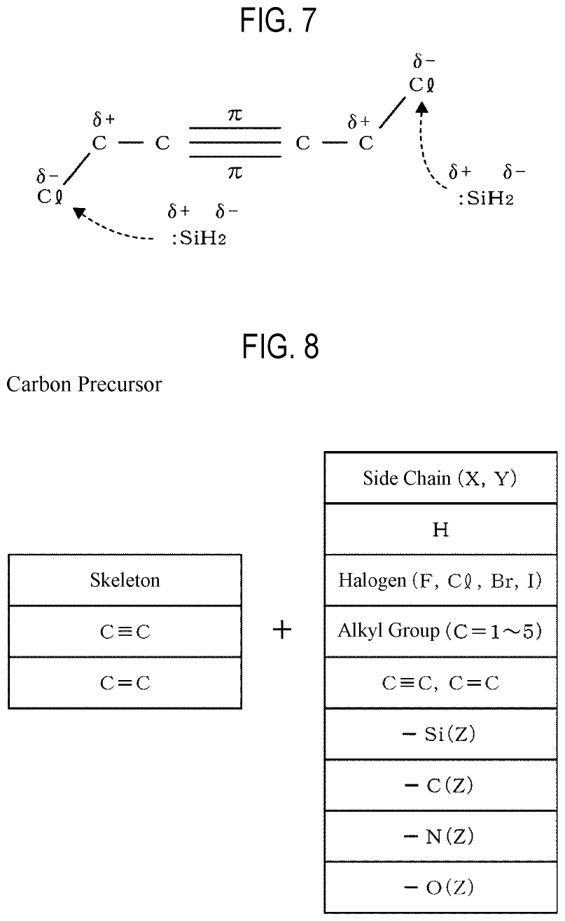

Next, the carbon precursor illustrated in FIG. 6 is bis(chloromethyl)acetylene (BCMA) having a triple bond which is an unsaturated carbon bond and containing a halogen. FIG. 6 illustrates an example in which a BCMA gas and a silicon precursor, for example, disilane gas, are thermally reacted at a temperature in the range of 300 degrees C. or higher and 500 degrees C. or lower. Regarding this thermal reaction, it is presumed that Reaction Model 1 illustrated in FIG. 3 and Reaction Model 2 illustrated in FIG. 7 proceed at the same time. Reaction Model 2 has nucleophilicity in which BCMA is polarized by having a halogen group (Cl group) and the positive polarization site (σ+) of a SiH₂ radical attacks the negative polarization site (σ−). In this way, the SiH₂ radical reacts with C at a molecular end where Cl is bonded, forming a SiC bond.

The carbon precursor containing an organic compound having an unsaturated carbon bond is not limited to the above-mentioned BTMSA, TMSA, TMSMA, and BCMA. Another carbon precursor may be used if it thermally reacts with the silicon precursor at a temperature of 500 degrees C. or lower to form a SiC film. As the carbon precursor, a combination of skeletons and side chains illustrated in FIG. 8 may be used. The skeleton of the carbon precursor is an unsaturated bond portion of an organic compound, and may be, for example, an unsaturated carbon bond of a triple bond or a double bond of C. The side chain of the carbon precursor is a portion that is bonded to the skeleton. Assuming that the skeleton is a triple bond, the side chain that is bonded to one C is X, and the side chain that is bonded to another C is Y. These side chains X and Y may be the same as or different from each other.

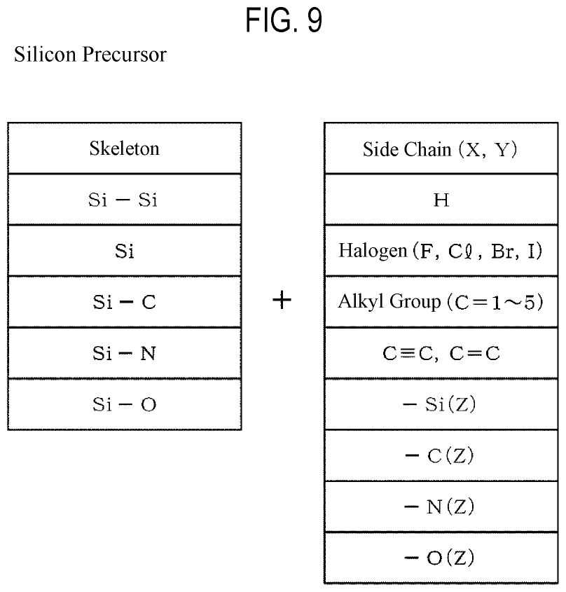

Examples of side chains include hydrogen (H) atoms, halogens, alkyl groups with a C number of 5 or less, triple bonds of C, double bonds of C, Si(Z), C(Z), N(Z), O(Z), and the like. In the tables illustrating the variations of side chains of FIGS. 8 and 9, Si(Z), C(Z), N(Z), and O(Z) are substances in which the sites bonded to C of the skeleton are Si, C, N, and O, respectively, and (Z) indicates an arbitrary atomic group.

As the silicon precursor, a combination of the skeletons and the side chains illustrated in FIG. 9 may be used. The skeleton of the silicon precursor is a Si—Si bond in terms of disilane. The side chain of the silicon precursor is a portion that is bonded to the skeleton. Assuming that the skeleton is Si—Si, the side chain X that is bonded to one Si and the side chain Y that is bonded to the other Si may be the same as or different from each other. Examples of the skeleton include Si—Si, Si, Si—C, Si—N, Si—O, and the like. Examples of side chains include hydrogen atoms, halogens, alkyl groups with a C number of 5 or less, triple bonds of C, double bonds of C, Si(Z), C(Z), N(Z), O(Z), and the like. Examples of silicon precursors that thermally decompose at a temperature of 500 degrees C. or lower to generate SiH₂ radicals include disilane, monosilane (SiH₄), and trisilane (Si₃H₈).

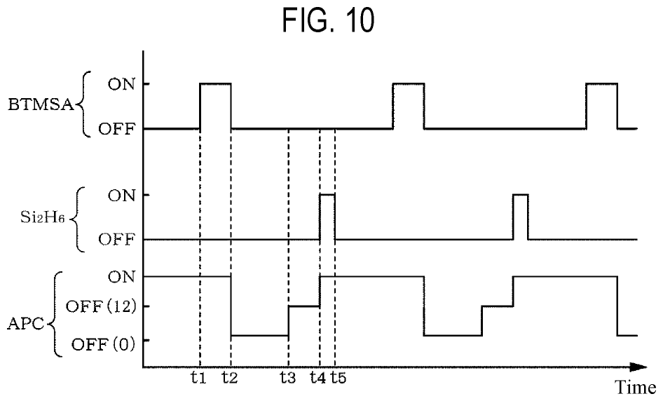

Subsequently, another example of the film forming method executed by the above-mentioned film forming apparatus will be described with reference to FIG. 10. FIG. 10 is a time chart illustrating the timing of starting and stopping the supply of BTMSA gas, which is a carbon precursor, and disilane gas, which is a silicon precursor, and the timing of opening/closing control of the APC valve 63. Illustration of each of the Ar(1) and Ar(2), which are purge gases, is omitted, but since these purge gases are supplied in the same manner as in the time charts illustrated in FIGS. 4A and 4B, a description thereof is omitted. In addition, how to read the time chart is the same as in FIGS. 4A and 4B.

In this example, control is performed such that the temporary restriction of vacuum exhaust is initiated after stopping the supply of a carbon precursor gas to the processing container 10 and then terminated after a lapse of a preset time. Specifically, the supply of BTMSA gas is initiated by opening the valve 514 at time t1, and the supply is stopped by closing the valve 514 at time t2. Meanwhile, the supply of disilane gas is initiated by opening the valve 524 at time t4, and the supply is stopped by closing the valve 524 at time t5. The pressure regulating function of the APC valve 63 is set to “ON” until time t2, that is, while the BTMSA gas is being supplied, and the control pressure of the interior of the processing container 10 is executed.

Then, at time t2, the supply of BTMSA gas is stopped, the APC valve 63 is fully closed, and the temporary restriction of vacuum exhaust is initiated. As a result, in the processing container 10, the exhaust flow rate decreases, the BTMSA gas stays, and the chemisorption of BTMSA on the wafer W proceeds.

Thereafter, at time t3, which is after a preset time has elapsed since the temporary restriction of vacuum exhaust was initiated at time t2, the opening degree of the APC valve 63 is set to, for example, “12%”, the temporary restriction of vacuum exhaust is terminated, and the interior of the processing container 10 is forcibly evacuated.

In the example illustrated in FIG. 10, the pressure regulating function of the APC valve 63 is set to “ON” when the disilane gas is supplied, but as in FIG. 4A, the APC valve 63 may be switched to the opening degree setting function to be fully closed only when the disilane gas is supplied. In this case, the supply of the disilane gas is stopped, the opening degree of the APC valve 63 is set to, for example, “12%”, purging is performed, and the interior of the processing container 10 is forcibly evacuated to discharge the excess disilane gas.

Here, in the film forming method of the present disclosure, the vacuum exhaust of the processing container 10 may be temporarily restricted in the adsorption step of adsorbing the organic compound of the carbon precursor on the wafer W. Therefore, it is not essential to initiate the restriction of vacuum exhaust in conjunction with the operations of supplying the carbon precursor and stopping the supply of the carbon precursor. For example, the restriction of vacuum exhaust may be initiated slightly later than time t1 in FIGS. 4A and 4B, which is the timing for initiating the supply of the carbon precursor gas to the processing container 10. In addition, the restriction of vacuum exhaust may be initiated slightly later than time t2 in FIG. 10, which is the timing for stopping the supply of the carbon precursor gas to the processing container 10.

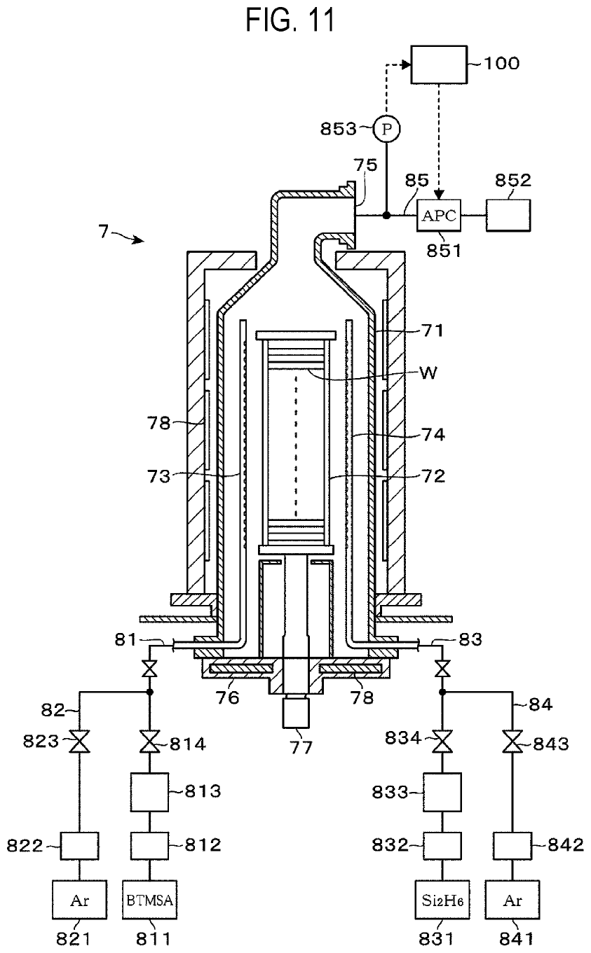

Subsequently, an example in which a batch-type vertical heat treatment apparatus, which is another embodiment of the film forming apparatus of the present disclosure, is applied to the film forming apparatus will be briefly described with reference to FIG. 11. In the film forming apparatus 7, a wafer boat 72 in which a large number of wafers W are loaded in a shelf shape is airtightly accommodated inside the reaction tube 71, which is a processing container made of quartz glass, from the lower side. Inside the reaction tube 71, two gas injectors 73 and 74 are disposed to face each other across the wafer boat 72 in the length direction of the reaction tube 71.

The gas injector 73 is connected to a gas source 811 of a carbon precursor, for example, BTMSA gas, via, for example, a gas supply path 81. In addition, the gas injector 73 is connected to a source 821 of a purge gas, for example Ar gas, via, for example, a branch path 82 branching from the gas supply path 81. The gas supply path 81 is provided with a flow rate regulator 812, a storage tank 813, and a valve 814 from the upstream side, and the branch path 82 is provided with a flow rate regulator 822 and a valve 823 from the upstream side. In this example, the carbon precursor supplier that supplies the carbon precursor gas to the reaction tube 71 includes the gas supply path 81 and the BTMSA gas source 811.

The gas injector 74 is connected to a source 831 of a silicon precursor, for example, disilane gas, via, for example, a gas supply path 83. In addition, the gas injector 74 is connected to a source 841 of Ar gas as a purge gas via, for example, a branch path 84 branching from the gas supply path 83. The gas supply path 83 is provided with a flow rate regulator 832, a storage tank 833, and a valve 834 from the upstream side, and the branch path 84 is provided with a flow rate regulator 842 and a valve 843 from the upstream side. In this example, the silicon precursor supplier that supplies the silicon precursor gas to the reaction tube 71 includes the gas supply path 83 and the disilane gas source 831.

An exhaust port 75 is formed at the upper end of the reaction tube 71, and the exhaust port 75 is connected to a vacuum exhauster 852 including a vacuum pump via a vacuum exhaust path 85 provided with an APC valve 851 that forms a pressure control valve. The vacuum exhaust path 85 is provided with a pressure detector 853 on the upstream side of the APC valve 851. The function of the APC valve 851 is the same as the configuration example illustrated in FIG. 1 described above.

In FIG. 11, reference numeral 76 indicates a lid configured to open/close the lower end opening of the reaction tube 71, and reference numeral 77 indicates a rotation mechanism configured to rotate the wafer boat 72 around a vertical axis. Heaters 78 are provided around the reaction tube 71 and in the lid 76 to heat the wafers W loaded on the wafer boat 72 to a temperature within a range of, for example, 300 degrees C. or higher and 500 degrees C. or lower.

In this film forming apparatus 7 as well, for example, a film forming process for forming a SiC film is performed according to the time chart illustrated in FIG. 4A, FIG. 4B or FIG. 10. For example, the step of accommodating wafers W into the reaction tube 71 is executed by carrying the wafer boat 72 mounted with wafers W and closing the lid 76 of the reaction tube 71. Next, the interior of the reaction tube 71 is vacuumized, and while supplying Ar gas by opening the valves 823 and 843, the interior of the reaction tube 71 is controlled to each of a pressure target value of, for example, 400 Pa, and a set temperature of 300 degrees C. or higher and 500 degrees C. or lower, for example, 390 degrees C.

Next, the step of adsorbing BTMSA on the wafer W is executed by opening the valve 814 and supplying the BTMSA gas, which is a carbon precursor, into the reaction tube 71. Subsequently, after closing the valve 814 and stopping the supply of BTMSA gas, the interior of the reaction tube 71 is purged with Ar gas. Next, the step of forming a SiC film is executed by opening the valve 834 to supply disilane gas, which is a silicon precursor, and reacting the BTMSA adsorbed on the wafer W with the disilane. Thereafter, after closing the valve 834 and stopping the supply of disilane gas, the interior of the reaction tube 71 is purged with Ar gas. By alternately repeating multiple times the BTMSA adsorbing step and the step of reacting BTMSA with disilane, a SiC film having a predetermined film thickness is formed.

Then, in the BTMSA adsorbing step, the APC valve 851 is fully closed to temporarily restrict the vacuum exhaust in the reaction tube 71, and the BTMSA gas is caused to stay in the reaction tube 71. Thereafter, the APC valve 851 is opened to release the temporary restriction on vacuum exhaust, and the BTMSA gas is discharged from the reaction tube 71. During the reaction step, the supply of disilane gas to the reaction tube 71 is stopped, and after stopping the supply, the restriction of vacuum exhaust is not performed, and the pressure regulating function of the APC valve 63 is set to “ON” to perform pressure control of the interior of the reaction tube pipe 71. Specifically, for example, supply of various gases and regulation of the opening degree of the APC valve 851 are performed according to the time chart of FIG. 4A, FIG. 4B or FIG. 10 described above. After executing the SiC film forming process in this way, the pressure inside the reaction tube 71 is restored to the pressure at the time of carry-in/out of the wafers W, then the lid 76 of the reaction tube 71 is opened, and the wafer boat 72 is lowered and carried out.

In this embodiment as well, in the step of adsorbing BTMSA on the wafers W, the vacuum exhaust of the reaction tube 71 is temporarily restricted. On the other hand, in the step of reacting the BTMSA adsorbed on the wafer W with the disilane, the temporary restriction of vacuum exhaust is not performed after stopping the supply of the disilane gas. Therefore, as in the embodiment described with reference to FIGS. 1, 4A, 4B, 10 and the like, it is possible to form a SiC film having good film quality at a high film forming rate.

In each of the above-described embodiments, the temporary limitation of vacuum exhaust is not limited to the case where the vacuum exhaust is executed by controlling the opening degree of the APC valve 63. For example, the temporary restriction of vacuum exhaust may be performed by reducing the exhaust amount of the vacuum exhauster, or by stopping the vacuum exhauster.

The embodiments disclosed herein should be considered to be exemplary in all respects and not restrictive. The embodiments described above may be omitted, replaced, or modified in various forms without departing from the scope and spirit of the appended claims.

### EXAMPLES

### Evaluation Experiment 1

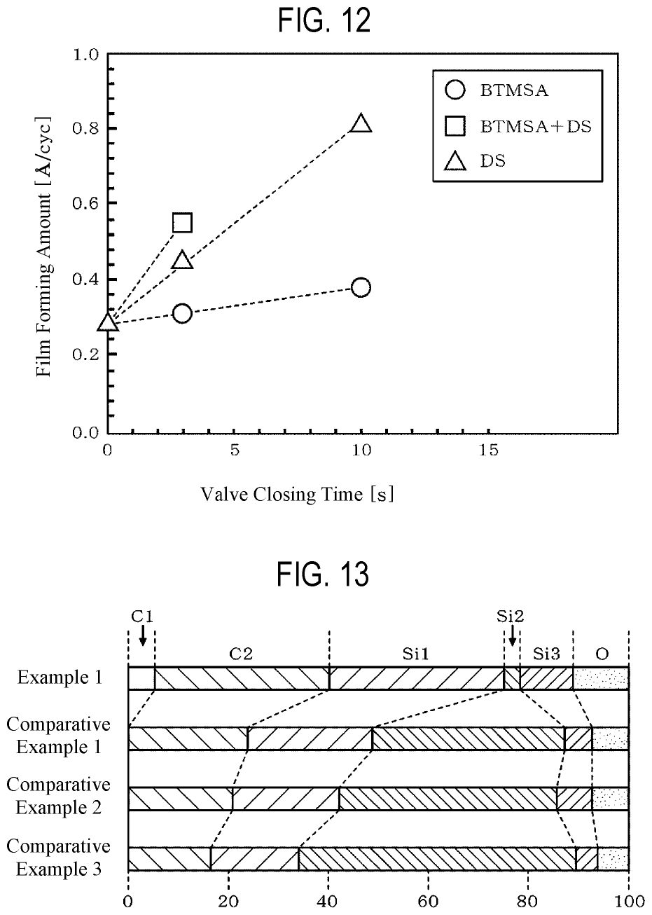

Evaluation experiments of the film forming method of the present disclosure will be described. FIG. 12 is a characteristic diagram showing an amount of a film formed when a SiC film is formed by an ALD method by using BTMSA as a carbon precursor, disilane as a silicon precursor, and Ar gas as a purge gas in the film forming apparatus 1 illustrated in FIG. 1. In order to form a SiC film, a wafer W was heated while supplying Ar gas into the processing container 10, the pressure in the processing container 10 was regulated to a pressure target value, and then steps 1 to 8 illustrated below are executed in order from step 1 to step 8.

Step 1: the step of vacuumizing the interior of the processing container 10 for 3 seconds while the pressure regulating function of the APC valve 63 is set to “ON”, and then switching the pressure regulating function of the APC valve 63 to “OFF” (the fully closed state).

Step 2: the step of adsorbing BTSMA on the wafer by supplying BTMSA gas for 1 second while the APC valve 63 is set to the “OFF” state (the fully closed state).

Step 3: the step of stopping the supply of BTMSA gas while the APC valve 63 is set to the “OFF” state (fully closed state), and causing the BTMSA gas to stay in the processing container 10 for x seconds.

Step 4: the step of purging the interior of the processing container 10 by switching the pressure regulating function of the APC valve 63 to “ON”, and supplying Ar gas for 5 seconds while performing pressure control of the interior of the processing container 10.

Step 5: the step of stopping supply of Ar gas and vacuumizing the interior of the processing container 10 for 3 seconds while the pressure regulating function of the APC valve 63 is set to “ON”, and then switching the pressure regulating function of the APC valve 63 to “OFF” to set the APC valve 63 to the fully closed state.

Step 6: the step of reacting BTMSA adsorbed on the wafer with disilane by supplying disilane gas for 1 second while the APC valve 63 is set to the “OFF” state (the fully closed state).

Step 7: the step of causing the disilane gas to stay for y seconds while the APC valve 63 is set to the “OFF” state (the fully closed state).

Step 8: the step of purging the interior of the processing container 10 by switching the pressure regulating function of the APC valve 63 to “ON”, and supplying Ar gas for 5 seconds while performing pressure control of the interior of the processing container 10.

The film forming process is performed under the process conditions described above, and the times for setting the APC valve 63 to the fully closed state (valve closing time) in step 3 and step 7 were set to the staying time of BTMSA gas (x seconds) and the staying time of disilane gas (y seconds), respectively.

In Example 1, a SiC film was formed under the condition that the staying times was provided only for the BTMSA gas (x seconds in step 3: 3 seconds and 10 seconds, y seconds in step 7: 0 seconds).

In Comparative Example 1, a SiC film was formed under the condition that the staying time was provided for both BTMSA gas and disilane gas (x seconds in step 3: 3 seconds, y seconds in step 7: 3 seconds).

In Comparative Example 2, a SiC film was formed by a method in the related arts, i.e., under the condition that the staying time was not provided for both BTMSA gas and disilane gas (x seconds in step 3: 0 seconds, y seconds in step 7: 0 seconds).

In Comparative Example 3, a SiC film was formed under the condition that the staying time was provided only for the disilane gas (x seconds in step 3: 0 seconds, y seconds in step 7: 3 seconds and 10 seconds).

The results are shown in FIG. 12. In FIG. 12, the horizontal axis represents valve closing time, and the vertical axis represents film thickness (film thickness (A) per cycle). Film thicknesses for calculating film forming amounts were measured by a scanning electron microscope (SEM). These film forming amounts are indicated by ◯ in Example 1, □ in Comparative Example 1, and Δ in Comparative Example 3. Since the data of Comparative Example 2 corresponds to the data of Comparative Example 3 when the valve closing time is 0 seconds, the illustration is omitted.

According to FIG. 12, in Example 1, it was found that the film forming amounts are increased by setting the valve closing time longer. From this, it is understood that it is possible to improve the film forming rate by temporarily restricting the vacuum exhaust in the processing container 10 to cause BTMSA gas to stay. Compared to Example 1, each of Comparative Examples 1 and 3 has a larger film forming amount. As is clear from Evaluation Experiment 2 below, this is because an amorphous Si film was formed in addition to the SiC film, and thus the apparent film forming amount was increased.

### Evaluation Experiment 2

For a SiC film formed by Example 1 under the condition of 10 seconds of step 3, a SiC film formed by Comparative Example 1 under the condition of 3 seconds of step 3 and the condition of 3 seconds of step 7, a SiC film of Comparative Example 2, and a SiC film formed by Comparative Example 3 under the condition of 10 seconds of step 7, the components of the SiC films were analyzed by an X-ray photoelectron spectroscopy (XPS). In FIG. 13, C1, C2, Si1, Si2, and Si3 indicate the following components.

C1: carbon atoms having a C—C bond and a C—H bond

C2: carbon atoms having a Si—C bond

Si1: Silicon atoms having a Si—C bond

Si2: Silicon atoms having a Si—Si bond

Si3: Silicon atoms having SiOₓ

As the results of the component analysis are shown in FIG. 13, it was found that the SiC film of Example 1 has more Si and C based on Si—C bonds than the SiC film of Comparative Example 2 formed by the conventional method, and the Si/C ratio is almost 1. As a result, it was confirmed that, by temporarily restricting vacuum exhaust in the processing container 10 and causing the BTMSA gas to stay, the Si—C bonds in the film are increased, so it is possible to obtain a SiC film having good film quality with an ideal Si/C ratio. Even when a carbon precursor such as BTMSA, which has less intramolecular polarization and is less likely to be chemisorbed on a wafer surface, was used, it was possible to form a SiC film having good film quality. In addition, it was also possible to improve the film forming rate.

In addition, in Comparative Examples 1 and 3 in which the vacuum exhaust in the processing container 10 was temporarily restricted in the disilane gas supply step to cause disilane gas to stay, the proportion of Si2 (Si atoms having a Si—Si bond) was much larger compared with Example 1. It is presumed that this is because the excess disilane gas generated due to the staying is thermally decomposed and forms an amorphous Si film. Accordingly, it is understood that it is preferable not to perform the restriction of vacuum exhaust in the processing container 10 in the disilane gas supply step.

Furthermore, focusing on film densities, Example 1 was 1.67 g/cm³, Comparative Example 1 was 2.01 g/cm³, Comparative Example 2 was 2.08 g/cm³, and Comparative Example 3 was 2.13 g/cm³. The film density of Example 1 is smaller than those of Comparative Examples 1 to 3, but it is presumed that since the larger the proportion of Si2 (silicon atoms having a Si—Si bond), the higher the film density in Comparative Examples 1 to 3, the differences in film density are caused due to the formation of an amorphous Si film.

### EXPLANATION OF REFERENCE NUMERALS

W: semiconductor wafer, 10: processing container, 2: stage, 51: carbon precursor source, 52: silicon precursor source, 61: vacuum exhauster, 62: vacuum exhaust path, 63: APC valve

1-14. (canceled)

15. A method of forming a silicon carbide-containing film on a substrate in a processing container in which vacuum exhaust is performed, the method comprising:
accommodating the substrate in the processing container;
adsorbing an organic compound having an unsaturated carbon bond on the substrate by supplying a carbon precursor gas including the organic compound to the processing container in which the substrate is accommodated; and
reacting the organic compound adsorbed on the substrate with a silicon compound by supplying a silicon precursor gas including the silicon compound to the processing container after the carbon precursor gas is supplied,
wherein the adsorbing the organic compound on the substrate and the reacting the organic compound with the silicon compound are alternately repeated multiple times to form the silicon carbide-containing film,
wherein, in the adsorbing the organic compound, the vacuum exhaust is restricted to cause the carbon precursor gas to stay in the processing container, and then the restriction of the vacuum exhaust is released to discharge the carbon precursor gas in the processing container, and
wherein the supply of the silicon precursor gas to the processing container is stopped during the reacting the organic compound adsorbed on the substrate with the silicon compound, and the vacuum exhaust is not restricted after the supply of the silicon precursor gas is stopped.

16. The method of claim 15, wherein the vacuum exhaust is executed by using a pressure regulating mechanism including: a vacuum exhaust path connected to the processing container; a vacuum exhauster provided on a downstream side of the vacuum exhaust path and configured to execute vacuum exhaust of gas in the processing container; and a pressure regulating valve provided in the vacuum exhaust path and configured to be opened and closed to regulate pressure in the processing container, and
wherein the restriction of the vacuum exhaust is executed by making an opening degree of the pressure regulating valve smaller than that before the restriction is initiated.

17. The method of claim 16, wherein the restriction of the vacuum exhaust in the adsorbing the organic compound is initiated during a period of supplying the carbon precursor gas to the processing container, and is terminated after a lapse of a preset time after the supply of the carbon precursor gas is stopped.

18. The method of claim 17, wherein the organic compound is selected from a group consisting of bis(trimethylsilyl)acetylene, bis(chloromethyl)acetylene, trimethylsilylacetylene, and [(trimethylsilyl)methyl]acetylene.

19. The method of claim 18, wherein the silicon compound is disilane.

20. The method of claim 19, wherein the adsorbing the organic compound on the substrate and the reacting the organic compound adsorbed on the substrate with the silicon compound are executed in a state in which the substrate is heated to a temperature within a range of 300 degrees C. or higher and 500 degrees C. or lower.

21. The method of claim 15, wherein the restriction of the vacuum exhaust in the adsorbing the organic compound is initiated during a period of supplying the carbon precursor gas to the processing container, and is terminated after a lapse of a preset time after the supply of the carbon precursor gas is stopped.

22. The method of claim 14, wherein the restriction of the vacuum exhaust in the adsorbing the organic compound is initiated after the supply of the carbon precursor gas to the processing container is stopped, and then is terminated after a lapse of a preset time.

23. The method of claim 15, wherein the organic compound is selected from a group consisting of bis(trimethylsilyl)acetylene, bis(chloromethyl)acetylene, trimethylsilylacetylene, and [(trimethylsilyl)methyl]acetylene.

24. The method of claim 15, wherein the silicon compound is disilane.

25. The method of claim 15, wherein the adsorbing the organic compound on the substrate and the reacting the organic compound adsorbed on the substrate with the silicon compound are executed in a state in which the substrate is heated to a temperature within a range of 300 degrees C. or higher and 500 degrees C. or lower.

26. An apparatus of forming a silicon carbide-containing film on a substrate, the apparatus comprising:
a processing container configured to accommodate the substrate;
a carbon precursor supplier configured to supply a carbon precursor gas including an organic compound having an unsaturated carbon bond to the processing container;
a silicon precursor supplier configured to supply a silicon precursor gas including a silicon compound to the processing container;
a vacuum exhauster configured to execute vacuum exhaust of gas in the processing container; and
a controller,
wherein the controller is configured to execute:
a control of forming the silicon carbide-containing film by alternately repeating multiple times a step of adsorbing the organic compound on the substrate by supplying the carbon precursor gas from the carbon precursor supplier to the processing container in which vacuum exhaust is performed by the vacuum exhauster and the substrate is accommodated and a step of reacting the organic compound adsorbed on the substrate with the silicon compound by supplying the silicon precursor gas from the silicon precursor supplier to the processing container after the carbon precursor gas is supplied to the processing container;
a control of the vacuum exhauster for restricting the vacuum exhaust to cause the carbon precursor gas to stay in the processing container in the step of adsorbing the organic compound, and then releasing the restriction of the vacuum exhaust to discharge the carbon precursor gas in the processing container; and
a control of stopping the supply of the silicon precursor gas to the processing container during the step of reacting the organic compound adsorbed on the substrate with the silicon compound, and continuing the vacuum exhaust by the vacuum exhauster such that the restriction of the vacuum exhaust is not performed after stopping the supply of the silicon precursor gas.

27. The apparatus of claim 26, further comprising:
a pressure regulating mechanism including:
a vacuum exhaust path connected to the processing container;
the vacuum exhauster provided on a downstream side of the vacuum exhaust path; and
a pressure regulating valve provided in the vacuum exhaust path and configured to be opened and closed to regulate a pressure in the processing container,
wherein the controller is configured to perform control such that the restriction of the vacuum exhaust is executed by making an opening degree of the pressure regulating valve smaller than that before the restriction is initiated.

28. The apparatus of claim 27, wherein the controller is configured to perform a control such that the restriction of the vacuum exhaust in the step of adsorbing the organic compound is initiated during a period of supplying the carbon precursor gas to the processing container, and is terminated after a lapse of a preset time after the supply of the carbon precursor gas is stopped.

29. The apparatus of claim 28, wherein the organic compound is selected from a group consisting of bis(trimethylsilyl)acetylene, bis(chloromethyl)acetylene, trimethylsilylacetylene, and [(trimethylsilyl)methyl]acetylene.

30. The apparatus of claim 29, wherein the silicon compound is disilane.

31. The apparatus of claim 30, further comprising:
a heater configured to heat the substrate in the processing container,
wherein the controller is configured to perform a control of heating the substrate to a temperature within a range of 300 degrees C. or higher and 500 degrees C. or lower by the heater when executing the step of adsorbing the organic compound on the substrate and the step of reacting the organic compound adsorbed on the substrate with the silicon compound.

32. The apparatus of claim 26, wherein the controller is configured to perform a control such that the restriction of the vacuum exhaust in the step of adsorbing the organic compound is initiated during a period of supplying the carbon precursor gas to the processing container, and is terminated after a lapse of a preset time after the supply of the carbon precursor gas is stopped.

33. The apparatus of claim 26, wherein the controller is configured to perform a control such that the restriction of the vacuum exhaust in the step of adsorbing the organic compound is initiated after stopping the supply of the carbon precursor gas to the processing container, and then is terminated after a lapse of a preset time.

34. The apparatus of claim 26, wherein the organic compound is selected from a group consisting of bis(trimethylsilyl)acetylene, bis(chloromethyl)acetylene, trimethylsilylacetylene, and [(trimethylsilyl)methyl]acetylene.
